(19) United States
(12) Patent Application Publication
(10) Pub. No.: US 2004/0080000 A1
(43) Pub. Date: Apr. 29, 2004

(54) Gate structure of metal oxide semiconductor field effect transistor

(75) Inventors: Bing-Yue Tsui, Hsinchu (TW); Chih-Feng Huang, Changhua (TW)

Correspondence Address: TROXELL LAW OFFICE PLLC, SUITE 1404, 5205 LEESBURG PIKE,, FALLS CHURCH, VA, 22041, US

(73) Assignee: National Chiao Tung University

(21) Appl. No.: 10/277,822

(22) Filed: Oct. 23, 2002

(51) Int. Cl. H01L 29/76

(52) U.S. Cl. 257/407

(57) ABSTRACT

The present invention provides an alloy system as metal gate material of MOSFET devices that can solve the issue of work function incompatibility of metal gate and then can achieve low threshold voltage of surface channel MOSFETs effectively to satisfy the requirement of low voltage and high performance operation. To achieve this purpose, a chemically inert and thermally stable element, platinum (Pt), with high work function is selected as the basic component, which is doped with low work function element, such as tantalum (Ta), or titanium (Ti) to various atomic ratios. The work function can be adjusted to arbitrary value depends on the atomic ratio of element. The metal alloy can be deposited with co-sputtering or co-evaporation method of physical vapor deposition to synthesize the suitable alloy of platinum (Pt) by adjustment of deposition rate of platinum (Pt) target and relative low work function metallic target, that can also be employed by simple sputtering on pre-formed platinum (Pt)—alloy target.

### REFERENCES CITED

1. C. D. Gelatt, et. al., “Charge transfer in alloy: AgAu”, in Phys. Rev. B 10 p. 398, 1974.

2. Ryusuke Ishii, et. al., “Work function of binary alloys”, in App. Surf. Science 169-170 (2001) P. 658-661.

3. Hunicai Zhong, et. al., “Properties of Ru-Ta Alloys as Gate Electrodes For NMOS and PMOS Silicon Devices” in Tech. Dig. of IEDM, p. 20.5.1-20.5.5.

4. Hitoshi Wakabayasi, et. al., “A Dual-Metal CMOS Technology Using Nitrogen-Concentration-Controlled TiNx Film”, In IEEE Trans. on Electron Devices, VOL. 48, No. 10, P, 2363 October 2001.

5. Qiang Lu, et. al., “Metal Gate Work Function Adjustment for Future CMOS Technology” in Symp. on VLSI Tech. Digest of Tech. Papers, p. 45-46, 2001.

6. Igor Polishchuk, et. al., “Dual Work Function Metal Gate Cmos Technology Using Metal Interdiffusion”, in IEEE Electron Device Letters, VOL. 22, No. 9, September 2001.

7. Yee-Chia Yeo, et. al., “Dual-Metal Gate CMOS Technology With Ultrathin Silicon Nitride Gate Dielectric”, in IEEE Electron Device Letters, VOL. 22, No. 5, May 2001.

8. Hitoshi Wakabayashi, et. al., “A Novel W/TiNx Metal Gate CMOS Technology Using Nitrogen-Concentration-Controlled TiNx Film”, in Tech. Dig. of IEDM, p. 10.4.1-10.4.4.

9. Dae-Gyu Park, et. al., “Rubust Ternary Metal Gate Electrodes for Dual Gate CMOS Devices”, in Tech. Dig. of IEDM, p. 30.6.1-30.6.3.

1. Field of the Invention

The present invention relates to new metal gate material. More particularly, the present invention employs low voltage and high performance operation for metal oxide semiconductor field effect transistors (MOSFET) and full depletion—silicon on insulator—metal oxide semiconductor field effect transistor (FD-SOI-MOSFET).

2. Background of the Invention

As conventional MOSFET devices are scaled down to improve performance, gate engineering becomes a crucial issue. It is well know that the gate structure of MOSFET for the conventional gate material, poly-silicon, is suffered from issues such as gate depletion to reduce equivalent oxide thickness, high gate resistance to block high frequency, boron penetration to drift threshold voltage. It is believed that using a metal gate of nano-scale instead of a poly-si gate can completely solve the gate depletion, high gate resistance and boron penetration problems to high performance for gate material of MOSFET.

In fact, new metal gate material must have high thermodynamic stability, work function adaptability and process compatibility. In the view of these properties, refractory metals and refractory metals nitrides are the attractive candidates. However, it is difficult to achieve low threshold voltage values for a surface channel of MOSFETs. This is the issue of work function incompatibility of the metal gate. The buried channel may find more current leakage of MOSFETs than that of doping surface channel. Although doping refractory metals with nitrogen can adjust work function, it can not solve the issue of buried channel, which causes undesirable NMOSFETs or PMOSFETs to current leakage problem.

C. D. Gelatt, et. Al., “Charge transfer in alloy: AgAu”, in Phys. Rev. B 10 p. 398, 1974, that discloses the work function can be changed depend on the atomic ratio of A and B element to alloy (AₓB_{y}). Ryusuke Ishii, et al., “Work function of binary alloys”, in App. Surf. Science 169-170 (2001) P. 658-661, that discloses the work function have linear or non-linear relationship depend on the composition of alloy, Hunicai Zhong, et. al., “Properties of Ru-Ta Alloys as Gate Electrodes for NMOS and PMOS Silicon Devices” In Tech, Dig. of IEDM, p. 20.5.1-20.5.5, that discloses the binary metallic alloy of Ruthenium (Ru) and tantalum (Ta) by controlling the composition thereby enabling its use in both NMOSFETs and PMOSFETs. Unfortunately, the Ruthenium (Ru) and tantalum (Ta) easily form a chemical compound; hence the work function have non-linear relationship depending on the atomic ratio of Ruthenium (Ru) and tantalum (Ta), which can not meet a mid gap work function of SOI MOSFETS.

In order to resolve the work function of the binary metallic alloy can be continuous large-scale modulation, thereby making suitable for use in all device applications. Therefore, metal must have excellent chemical inertia and high thermodynamic stability to be selected as a high work function element which is doped with relative low work function element to form alloys, Furthermore, the work function of the alloy can be adjusted to arbitrary value In addition, it is widely applied as a metal gate electrode due to its high thermal stability and process compatibility.

### OBJECT OF THIS INVENTION

Therefore, the present invention provides a gate structure of metal oxide semiconductor field effect transistor (MOSFET).

The main object of the present invention is to provide continuous large-scale modulation of work function to satisfy the low voltage and high performance of gate material of MOSFET.

Another object of the present invention is to provide low power consumption for gate structure of MOSFET.

The other object of the present invention is to provide low current leakage for gate structure of MOSFET.

### SUMMARY OF THE INVENTION

Accordingly, the present invention discloses adjusted work function with binary metallic alloy, that must have excellent chemical inertia and work function adaptability to be selected as the basic component which is doped with relative low work function element (such as: tantalum (Ta) or titanium (Ti)), thereby can be suitable for gate structure of metal oxide semiconductor field effect transistor (MOSFET) for low voltage and high performance operation. Using the binary metallic alloy as a metal gate electrode can completely solve the gate depletion, boron penetration, refractory metals nitrides low modulation, and alloy discontinuous modulation.

### BRIEF DESCRIPTION OF THE DRAWINGS

The present invention will be better understood from the following detailed description of preferred embodiments of the invention, taken in conjunction with the accompanying drawings, in which

FIG. 1 is a normalized C-V curve of metal oxide semiconductor field effect transistor (MOSFET) according to the present invention;

FIG. 2 is a work function versus gate material according to the present invention;

FIG. 3 is a schematic cross section of single layer metal gate electrode of MOSFET according to the present invention;

FIG. 4 is a schematic cross section of single layer metal gate electrode of full depletion—silicon on insulator—metal oxide semiconductor field effect transistor (FD-SOI-MOSFET) according to the present invention;

FIG. 5 is a schematic cross section of double layer metal gate electrode of MOSFET according to the present invention; and

FIG. 6 is a schematic cross section of double layer metal gate electrode of FD-SOI-MOSFET according to the present invention.

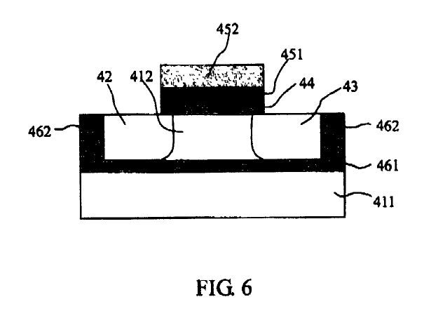

### DESCRIPTION OF THE PREFERRED EMBODIMENTS

The following descriptions of the preferred embodiments are provided to understand the features and the structures of the present invention.

The present invention is to disclose work function modulation with metallic alloy, that must have excellent chemical inertia and work function adaptability to be selected as the basic component which is doped with relative low work function element, it can be suitable for gate structure of metal oxide semiconductor field effect transistor (MOSFET). Thus, the object of the present invention is to provide steady and substantially continuous large-scale modulation of work function for alloy system to satisfy gate material of MOSFET which is low voltage and high performance operation, wherein said high work function element is selected from the group consisting of platinum (Pt) and tantalum (Ta), and said relative low work function element is selected from the group consisting of tantalum (Ta) and titanium (TI). The metal alloy can be deposited with co-sputtering or co-evaporation method of physical vapor deposition to synthesize the suitable alloy of platinum (Pt) by adjustment of deposition rate of platinum (Pt) target and relative low work function metallic target, that can also be employed by simple sputtering on pre-formed platinum (Pt)—alloy target. The following descriptions of the preferred embodiments are provided to illustrate alloy of platinum (Pt)—tantalum (Ta) and alloy of platinum (Pt)—titanium (Ti) for the present invention.

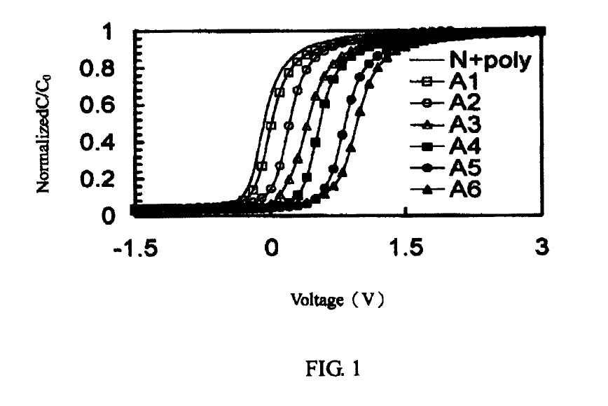

Alloy of platinum (Pt)—tantalum (Ta) and alloy of platinum (Pt)—titanium (Ti) can be deposited with co-sputtering method on a 10 nm thick layer of oxide at silicon wafer, and the gate electrodes are patterned using the lift-off process. The proportion of alloy is adjusted with the various sputtering powers for two metallic targets, that is controlled with deposition rate. Please referring to the FIG. 1 of a normalized C-V curve of MOSCAP, it show the C-V curve shifts toward the horizontal according to different work function, wherein N⁺ poly is a gate material for n-type poly-silicon, A1 is gate material for alloy of 63% tantalum (Ta)—37% titanium (Ti), A2 is gate material of 100% tantalum (Ta), A3 is gate material of alloy of 26% platinum (Pt)—74% tantalum (Ta), A4 is gate material of alloy of 35% platinum (Pt)—65% tantalum (Ta), A5 is gate material of alloy of 42% platinum (Pt)—58% tantalum (Ta), A6 is gate material of 100% platinum (Pt).

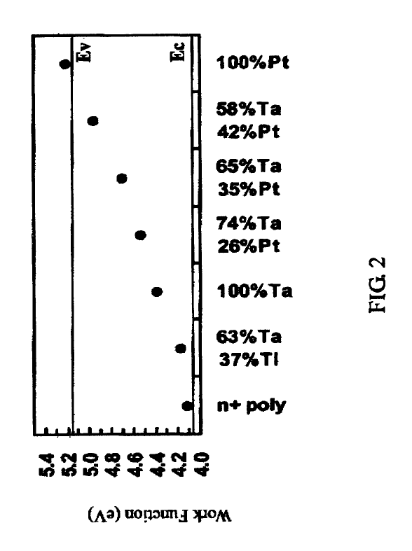

Next, please seeing the FIG. 2, it is a work function for gate material according to FIG. 1, and it can be continuous large-scale modulation with adjusting atomic composition of the alloy, wherein alloy of 63% tantalum (Ta)—37% titanium (Ti) shows work function of about 4.2 eV which is close to work function of n-type poly-si and is suitable for gate material of NMOSFETs, alloy of 26% platinum (Pt)—74% tantalum (Ta) shows work function of about 4.6 eV and is suitable for fully—deplete silicon on insulator (SOI) devices, alloy of 35% platinum (Pt)—65% tantalum (Ta) shows work function of about 5.0 eV and is suitable for gate material of PMOSFETs.

The present invention is illustrated in detail with the following examples, which should not be construed as limiting the scope of the invention.

### EXAMPLE 1

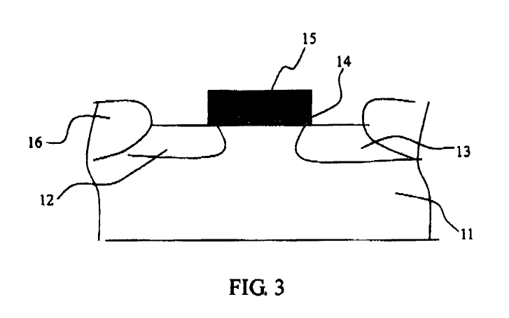

Please referring to the FIG. 3 of a schematic cross section of single layer metal gate electrode MOSFET according to the present invention, comprising a semiconductor substrate 11, a source region 12, a drain region 13, a isolation layer 16, a gate insulator 14 and a metal gate electrode 15, wherein said source region 12 for supporting injection carrier, said drain region 13 for accepting injection carrier, said isolation layer 16 for isolating neighbor devices to avoid from the electrical disturbance, said gate insulator 14 formed on said semiconductor substrate for isolating said semiconductor substrate and metal gate electrode, said metal gate electrode 15 controlling the threshold voltage of MOSFET, for example of p-type single layer metal gate electrode of MOSFET having n-type semiconductor substrate to meet threshold voltage located between −0.2V and −0.4V, and being binary metallic alloy which consists of a high work function element and a relative low work function element to meet work function of binary metallic alloy located between 4.8 eV and 5.1 eV, wherein said high work function element having a work function higher than 5.1 eV and relative low work function element having a work function lower than 4.8 eV. The said metal gate electrode 15 is non-obviousness and useful, and the further illustrated by:

1. The said metal gate electrode 15 is binary metallic alloy which consists of platinum (Pt) of high work function element and tantalum (Ta) of relative low work function element.

2. The said metal gate electrode 15 is binary metallic alloy which consists of platinum (Pt) of high work function element and titanium (Ti) of relative low work function element.

3. The said metal gate electrode 15 is binary metallic alloy which consists of platinum (Pt) of high work function element and tantalum (Ta) of relative low work function element, wherein the Pt:Ta ratio is equal to 42:58.

Next, for further illustration of N-type single layer metal gate electrode of MOSFET have P-type semiconductor substrate 11. The said metal gate electrode 15 is used to control the threshold voltage to meet the value located between 0.2V and 0.4V, and is binary metallic alloy which consists of a high work function element and a relative low work function element to meet work function of binary metallic alloy located between 4.0 eV and 4.2 eV, wherein said high work function element having a work function higher than 4.2 eV and relative low work function element having a work function lower than 4.0 eV. The said metal gate electrode 15 is non-obviousness and useful, and the further illustrated by:

1. The said metal gate electrode 15 is binary metallic alloy which consists of platinum (Pt) of high work function element and titanium (Ti) of relative low work function element.

2. The said metal gate electrode 15 is binary metallic alloy which consists of tantalum (Ta) of high work function element and titanium (Ti) of relative low work function element.

3. The said metal gate electrode 15 is binary metallic alloy which consists of tantalum (Ta) of high work function element and titanium (Ti) of relative low work function element, wherein the Ta:Ti ratio is equal to 63:37.

### EXAMPLE 2

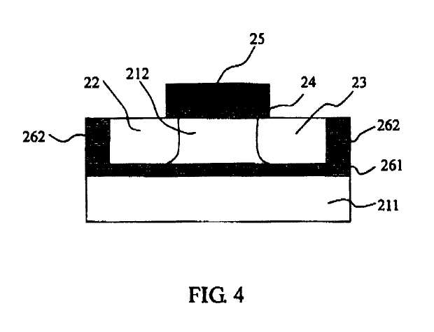

Please referring to the FIG. 4 of a schematic cross section of single layer metal gate electrode full depletion—silicon on insulator—metal oxide semiconductor field effect transistor (FD-SOI-MOSFET) according to the present invention, comprising a semiconductor substrate 211, a first isolation layer 261, a semiconductor layer 212, a source region 22, a drain region 23, a second isolation layer 262, a gate insulator 24 and a metal gate electrode 25, wherein said first isolation layer 261 formed on said semiconductor substrate 211 for isolating said semiconductor substrate 211 and said semiconductor layer 212, said semiconductor layer 212 for a channel to connect said source region 22 and said drain region 23, said source region 22 for supporting injection carrier, said drain region 23 for accepting injection carrier, said second isolation layer 262 for isolating neighbor devices to avoid form the electrical disturbance, said gate insulator 24 formed on said semiconductor layer 212 for isolating said semiconductor layer 212 and metal gate electrode 25, said metal gate electrode 25 controlling the threshold voltage of MOSFET, for example of N-type single layer metal gate electrode FD-SOI-MOSFET to meet threshold voltage located between 0.2V and 0.4V, and being binary metallic alloy which consists of a high work function element and a relative low work function element to meet work function of binary metallic alloy located between 4.5 eV and 4.7 eV, wherein said high work function element having a work function higher than 4.7 eV and relative low work function element having a work function lower than 4.5 eV. The said metal gate electrode 25 is non-obviousness and useful, and the further illustrated by:

1. The said metal gate electrode 25 is binary metallic alloy which consists of platinum (Pt) of high work function element and tantalum (Ta) of relative low work function element.

2. The said metal gate electrode 25 is binary metallic alloy which consists of platinum (Pt) of high work function element and titanium (Ti) of relative low work function element.

3. The said metal gate electrode 25 is binary metallic alloy which consists of platinum (Pt) of high work function element and tantalum (Ta) of relative low work function element, wherein the Pt:Ta ratio is equal to 26:27.

Next, for further illustration of P-type single layer metal gate electrode of FD-SOI-MOSFET having P-type semiconductor substrate 211. The said metal gate electrode 25 is used to control the threshold voltage to meet the value located between −0.2V and −0.4V, and is binary metallic alloy which consists of a high work function element and a relative low work function element to meet work function of binary metallic alloy located between 4.5 eV and 4.7 eV, wherein said high work function element having a work function higher than 4.7 eV and relative low work function element having a work function lower than 4.5 eV. The said metal gate electrode 25 is non-obviousness and useful, and the further illustrated by:

1. The said metal gate electrode 25 is binary metallic alloy which consists of platinum (Pt) of high work function element and tantalum (Ta) of relative low work function element.

2. The said metal gate electrode 25 is binary metallic alloy which consists of platinum (Pt) of high work function element and titanium (Ti) of relative low work function element.

3. The said metal gate electrode 25 is binary metallic alloy which consists of platinum (Pt) of high work function element and tantalum (Ta) of relative low work function element, wherein the Pt:Ta ratio is equal to 26:74.

### EXAMPLE 3

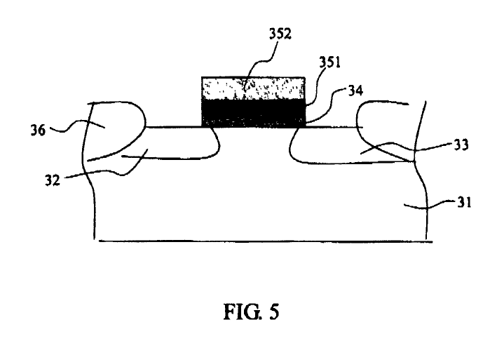

Please referring to the FIG. 5 of a schematic cross section of double layer metal gate electrode of MOSFET according to the present invention, comprising a semiconductor substrate 31, a source region 32, a drain region 33, a isolation layer 36, a gate insulator 34, a first metal gate electrode 351 and a second metal gate electrode 352, wherein said source region 32 for supporting injection carrier, said drain region 33 for accepting injection carrier, said isolation layer 36 for isolating neighbor devices to avoid form the electrical disturbance, said gate insulator 34 formed on said semiconductor substrate 31 for isolating said semiconductor substrate 31 and first metal gate electrode 351, said first metal gate electrode 351 controlling the threshold voltage of P type double layer metal gate electrode of MOSFET to meet the value located between −0.2V and −0.4V, and being binary metallic alloy which consists of a high work function element and a relative low work function element to meet work function of binary metallic alloy located between 4.8 eV and 5.1 eV, wherein said high work function element having a work function higher than 5.1 eV and relative low work function element having a work function lower than 4.8 eV, said second metal gate electrode 352 being selected from the group consisting of molybdenum (Mo), tungsten (W) and tantalum (Ta) for gate conduction layer with relative low resistivity to said first metal gate electrode. The said first metal gate electrode 351 is non-obviousness and useful, and the further illustrated by:

1. The said first metal gate electrode 351 is binary metallic alloy which consists of platinum (Pt) of high work function element and tantalum (Ta) of relative low work function element.

2. The said first metal gate electrode 35 is binary metallic alloy which consists of platinum (Pt) of high work function element and titanium (Ti) of relative low work function element.

3. The said first metal gate electrode 35 is binary metallic alloy which consists of platinum (Pt) of high work function element and tantalum (Ta) of relative low work function element, wherein the Pt:Ta ratio is equal to 42:58.

Next, for further illustration of N-type double layer metal gate electrode of MOSFET have P-type semiconductor substrate 31. The said first metal gate electrode 351 is used to control the threshold voltage to meet the value located between 0.2V and 0.4V, and is binary metallic alloy which consists of a high work function element and a relative low work function element to meet work function of binary metallic alloy located between 4.0 eV and 4.2 eV, wherein said high work function element having a work function higher than 4.2 eV and relative low work function element having a work function lower than 4.0 eV, said second metal gate electrode 352 being selected from the group consisting of molybdenum (Mo), tungsten (W) and tantalum (Ta) for gate conduction layer with relative low resistivity to said first metal gate electrode. The said first metal gate electrode 351 is non-obviousness and useful, and the further illustrated by:

1. The said first metal gate electrode 351 is binary metallic alloy which consists of platinum (Pt) of high work function element and tantalum (Ta) of relative low work function element.

2. The said first metal gate electrode 351 is binary metallic alloy which consists of tantalum (Ta) of high work function element and titanium (Ti) of relative low work function element.

3. The said first metal gate electrode 351 is binary metallic alloy which consists of platinum (Pt) of high work function element and tantalum (Ta) of relative low work function element, wherein the Ta:Ti ratio is equal to 63:37.

### EXAMPLE 4

Please referring to the FIG. 5 of a schematic cross section of double layer metal gate electrode of FD-SOI-MOSFET according to the present invention, comprising a semiconductor substrate 411, a first isolation layer 481, a semiconductor layer 412, a source region 42, a drain region 43, a second isolation layer 482, a gate insulator 44 a first metal gate electrode 451 and a second metal gate electrode 452, wherein said first isolation layer 461 formed on said semiconductor substrate 411 for isolating said semiconductor substrate 411 and said semiconductor layer 412, said semiconductor layer 412 for a channel to connect said source region 42 and said drain region 43, said source region 42 for supporting injection carrier, said drain region 43 for accepting injection carrier, said second isolation layer 462 for isolating neighbor devices to avoid form the electrical disturbance, said gate insulator 44 formed on said semiconductor layer 412 for isolating said semiconductor layer 412 and first metal gate electrode 451, said first metal gate electrode 451 controlling the threshold voltage of N-type double layer metal gate electrode of FD-SOI-MOSFET to meet the value located between 0.2V and 0.4V, and being binary metallic alloy which consists of a high work function element and a relative low work function element to meet work function of binary metallic alloy located between 4.5 eV and 4.7 eV, wherein said high work function element having a work function higher than 4.7 eV and relative low work function element having a work function lower than 4.5 eV, said second metal gate electrode 452 being selected from the group consisting of molybdenum (Mo), tungsten(W) and tantalum (Ta) for gate conduction layer with relative low resistivity to said first metal gate electrode. The said first metal gate electrode 451 is non-obviousness and useful, and the further illustrated by:

1. The said first metal gate electrode 451 is binary metallic alloy which consists of platinum (Pt) of high work function element and tantalum (Ta) of relative low work function element.

2. The said first metal gate electrode 451 is binary metallic alloy which consists of platinum (Pt) of high work function element and titanium (Ti) of relative low work function element.

3. The said first metal gate electrode 451 is binary metallic alloy which consists of platinum (Pt) of high work function element and tantalum (Ta) of relative low work function element, wherein the Pt:Ta ratio is equal to 74:26.

Next, for further illustration of P-type double layer metal gate electrode of FD-SOI-MOSFET have P-type semiconductor substrate 411. The said first metal gate electrode 451 is used to control the threshold voltage to meet the value located between 0.2V and 0.4V, and is binary metallic alloy which consists of a high work function element and a relative low work function element to meet work function of binary metallic alloy located between 4.5 eV and 4.7 eV, wherein said high work function element having a work function higher than 4.7 eV and relative low work function element having a work function lower than 4.5 eV, said second metal gate electrode 452 being selected from the group consisting of molybdenum (Mo), tungsten (W) and tantalum (Ta) for gate conduction layer with relative low resistivity to said first metal gate electrode. The said first metal gate electrode 451 is non-obviousness and useful, and the further illustrated by:

1. The said first metal gate electrode 451 is binary metallic alloy which consists of platinum (Pt) of high work function element and tantalum (Ta) of relative low work function element.

2. The said first metal gate electrode 451 is binary metallic alloy which consists of platinum (Pt) of high work function element and titanium (Ti) of relative low work function element.

3. The said first metal gate electrode 451 is binary metallic alloy which consists of platinum (Pt) of high work function element and tantalum (Ta) of relative low work function element, wherein the Pt:Ta ratio is equal to 26:74.

The present invention is to disclose a adjusted work function of gate structure of MOSFETs with metallic alloy, platinum (Pt) have excellent chemical inertia and work function adaptability to be selected as the basic component which is doped with relative low work function element, such as tantalum (Ta) or titanium (Ti). Thus, it can achieve low threshold voltage of surface channel MOSFETs effectively to satisfy the requirement of low voltage and high performance operation, which does not only possess a better practicality, neither only a conception based on familiarity of utilization, it is non-obviousness.

It is well know that the gate structure of MOSFET for the conventional gate material, poly-silicon is suffered from issues such as gate depletion to reduce equivalent oxide thickness, high gate resistance to block high frequency, boron penetration to drift threshold voltage. The present invention is to disclose the gate material of high work function element have excellent chemical inertia and thermodynamic stability, which is doped with relative low work function element. The work function can be adjusted to arbitrary value depends on the atomic ratio of element. Thus, it has process compatibility for gate structure of MOSFET, and it also reduces threshold voltage of the surface channel of transistor to achieve the low voltage and low power consumption for MOSFET, which is not only a reasonable and perfect invention, but also transcended conventional technology. It is novelty.

Moreover, this invention may be widely applied for gate structure of MOSFET Further, MOSFET is fundamental element of every integrated circuit. It is useful.

In summation of the foregoing section, the invention herein fully complies will all new patent application requirement and is hereby submitted to the patent bureau for review and granting of the commensurate patent rights.

The present invention may be embodied in other specific forms without departing from the spirit of the essential attributes thereof; therefore, the illustrated embodiment should be considered in all respects as illustrative and not restrictive, reference being made to the appended claims rather than to the foregoing description to indicate the scope of the invention.

What is claimed is:

1 A structure of metal oxide semiconductor field effect transistor (MOSFET) at least comprising a semiconductor substrate, a source region for supporting injection carrier, a drain region for accepting injection carrier, a isolation layer for isolating neighbor metal oxide semiconductor field effect transistors (MOSFET) to avoid from the electrical disturbance, a gate insulator formed on said semiconductor substrate for isolating said semiconductor substrate and metal gate electrode, a metal gate electrode and the further characterized by:
said metal gate electrode controlling the threshold voltage of said metal oxide semiconductor field effect transistor (MOSFET) and being metallic alloy which at least comprises a high work function element and a relative low work function element.

2 The structure of claim 1, wherein said high work function element is selected from the group consisting of platinum (Pt) and tantalum (Ta), and said relative low work function element is selected from the group consisting of tantalum (Ta) and titanium (Ti).

3 The structure of claim 1, wherein said semiconductor substrate is selected from the group consisting of P-type semiconductor substrate and N-type semiconductor substrate.

4 A structure of full depletion—silicon on insulator—metal oxide semiconductor field effect transistor (FD-SOI-MOSFET) at least comprising a semiconductor substrate, a first isolation layer formed on said semiconductor substrate for isolating said semiconductor substrate and semiconductor layer, a semiconductor layer for a channel to connect source region and drain region, a source region for supporting injection carrier, a drain region for accepting injection carrier, a second isolation layer for isolating neighbor devices to avoid form the electrical disturbance, a gate insulator formed on said semiconductor layer for isolating said semiconductor layer and metal gate electrode, a metal gate electrode and the further characterized by:
said metal gate electrode controlling the threshold voltage of metal oxide semiconductor field effect transistor (MOSFET) and being metallic alloy which at least comprises a high work function element and a relative low work function element.

5 The structure of claim 4, wherein said high work function element is selected from the group consisting of platinum (Pt) and/or tantalum (Ta), and said relative low work function element is selected from the group consisting of tantalum (Ta) and titanium (Ti).

6 The structure of claim 4, wherein said semiconductor substrate is selected from the group consisting of P type semiconductor substrate and N type semiconductor substrate.

7 A structure of double layer metal gate electrode of metal oxide semiconductor field effect transistor (MOSFET) at least comprising a semiconductor substrate, a source region for supporting injection carrier, a drain region for accepting injection carrier, a isolation layer for isolating neighbor devices to avoid form the electrical disturbance, a gate insulator formed on said semiconductor substrate for isolating said semiconductor substrate and first metal gate electrode, a first metal gate electrode, a second metal gate electrode and the further characterized by:
said first metal gate electrode controlling the threshold voltage of metal oxide semiconductor field effect transistor (MOSFET) and being metallic alloy which at least comprises a high work function element and a relative low work function element; and
said second metal gate electrode for gate conduction layer with relative low resistivity to said first metal gate electrode.

8 The structure of claim 7, wherein said high work function element is selected from the group consisting of platinum (Pt) and tantalum (Ta), and said relative low work function element is selected from the group consisting of tantalum (Ta) and titanium (Ti).

9 The structure of claim 7, wherein said semiconductor substrate is selected from the group consisting of P-type semiconductor substrate and N-type semiconductor substrate.

10 The structure of claim 7, wherein said second metal gate electrode is selected from the group consisting of molybdenum (Mo), tungsten (W) and tantalum (Ta).

11 A structure of double layer metal gate electrode of full depletion—silicon on insulator—metal oxide semiconductor field effect transistor (FD-SOI-MOSFET) at least comprising a semiconductor substrate, a first isolation layer formed on said semiconductor substrate for isolating said semiconductor substrate and semiconductor layer, a semiconductor layer for a channel to connect source region and drain region, a source region for supporting injection carrier, a drain region for accepting injection carrier, a second isolation layer for isolating neighbor devices to avoid form the electrical disturbance, a gate insulator formed on said semiconductor layer for isolating said semiconductor layer and first metal gate electrode, a first metal gate electrode, a second metal gate electrode and the further characterized by:
said first metal gate electrode controlling the threshold voltage of said metal oxide semiconductor field effect transistor (MOSFET) and being metallic alloy which at least comprises a high work function element and a relative low work function element; and
said second metal gate electrode for gate conduction layer with relative low resistivity to said first metal gate electrode.

12 The structure of claim 11, wherein said semiconductor substrate is selected from the group consisting of P-type semiconductor substrate and N-type semiconductor substrate.

13 The structure of claim 11, wherein said second metal gate electrode is selected from the group consisting of molybdenum (Mo), tungsten (W) and tantalum (Ta).

14 A gate structure of metal oxide semiconductor field effect transistor (MOSFET), said gate structure characterized by:
said gate structure being metallic alloy which at least comprises a high work function element and a relative low work function element.

15 The structure of claim 14, wherein said high work function element is selected from the group consisting of platinum (Pt) and tantalum (Ta), and said relative low work function element is selected from the group consisting of tantalum (Ta) and titanium (Ti).
